(19) United States
(12) Patent Application Publication
(10) Pub. No.: US 2010/0109809 A1
(43) Pub. Date: May 6, 2010

(54) THIN FILM PIEZOELECTRIC RESONATOR AND THIN FILM PIEZOELECTRIC FILTER

(76) Inventors: Kensuke Tanaka, Yamaguchi (JP); Kazuki Iwashita, Yamaguchi (JP); Hiroshi Tsuchiya, Yamaguchi (JP)

Correspondence Address: FROMMER LAWRENCE & HAUG, 745 FIFTH AVENUE- 10TH FL., NEW YORK, NY, 10151, US

(21) Appl. No.: 12/522,857

(22) PCT Filed: Jan. 17, 2008
(86) PCT No.: PCT/JP2008/050519

§ 371 Date: Jul. 10, 2009

(30) Foreign Application Priority Data
Jan. 17, 2007 (JP) 2007-008028

(51) Int. Cl. H03H 9/00

(52) U.S. Cl. 333/187; 333/219.1

(57) ABSTRACT

Provided is a thin film piezoelectric resonator which includes a piezoelectric resonator stack (12) having a piezoelectric layer (2), an upper electrode (10) and a lower electrode (8); and a substrate (6) which supports the piezoelectric resonator stack. The piezoelectric resonator stack (12) is provided with a vibration region (18) wherein the upper electrode (10) and the lower electrode (8) face each other through a piezoelectric layer (2) and primary thickness vertical vibration can be performed; and a supporting region (19) supported by the substrate (6). The vibration region (18) has an oval shape with a ratio a/b of 1.1 or more but not more than 1.7, where (a) is a long diameter and (b) is a short diameter. The piezoelectric resonator stack (12) is further provided with an upper dielectric layer (20) formed on the upper electrode (10). When the total of the thickness of the upper electrode (10) and that of the upper dielectric layer (20) in the vibration region (18) is expressed as (c), and the thickness of the piezoelectric layer (2) in the vibration region (18) is expressed as (d), a ratio c/d is 0.25 or more but not more than 0.45.

### TECHNICAL FIELD

The present invention belongs to a technical field of communication devices, and is particularly related to a thin film piezoelectric resonator and a thin film piezoelectric filter employing the thin film piezoelectric resonator. The present invention is particularly related to the structure of the thin film piezoelectric resonator intended to reduce noise related to spurious mode.

### BACKGROUND ART

There is always a demand for a RF circuit section of a cellular phone to be made small. Recently, there is a demand that various functions should be added to the cellular phone. To add various functions, it is desirable that more components be incorporated. Meanwhile, there is a limit on the size of the cellular phone. Therefore, it is strictly required that an area occupied by each component of the device (which is an area on which each component is mounted) and the height of each component be reduced. Accordingly, as for components constituting the RF circuit section, those whose occupying area is small and whose height is low are required.

Given such circumstances, as a band-pass filter used in the RF circuit, the thin film piezoelectric filter employing the thin film piezoelectric resonator that is small and can be made lighter is now being used. Such a thin film piezoelectric filter is a RF filter employing the thin film piezoelectric resonator where a piezoelectric layer made of aluminum nitride (AlN), zinc oxide (ZnO) or the like is formed on a semiconductor substrate such that the piezoelectric layer is sandwiched between an upper electrode and a lower electrode and where an air hole or air gap, or a sound reflecting layer (an acoustic impedance converter) is provided immediately below the sandwiched piezoelectric layer to prevent elastic wave energy from leaking into the semiconductor substrate.

In that manner, the thin film piezoelectric resonators are divided broadly into two types. First, there is Film Bulk Acoustic Resonator (FBAR) which is provided with an air gap immediately below a piezoelectric resonant stack including an upper electrode, a lower electrode, and a piezoelectric layer. Second, there is Surface Mounted Resonator (SMR) whose piezoelectric resonant stack is formed on an acoustic impedance converter where two types of layers are alternately stacked on a substrate, wherein the acoustic impedance of one layer is different from that of the other.

The above-mentioned FBAR and SMR are a resonator that uses an elastic wave (a longitudinal acoustic mode) propagating in the direction of the thickness of the piezoelectric resonant stack. The elastic wave excited by an AC signal applied to the upper and lower electrodes propagates in the direction of the thickness of the piezoelectric resonant stack, and then is reflected by a plane that is in contact with air around an upper surface of the upper electrode and a lower surface of the lower electrode, or the acoustic impedance converter. Therefore, when the weighted distance between the upper surface of the upper electrode and the lower surface of the lower electrode is equal to an integral multiple of a half wavelength of the elastic wave, elastic resonance occurs.

This resonance occurs in a region of the piezoelectric resonant stack corresponding to the air gap or the acoustic impedance converter. This region is referred to as a vibration region. In the vibration region, the upper electrode and the lower electrode are positioned all over the upper surface and the lower surface of the piezoelectric layer, respectively.

Meanwhile, in the thin film piezoelectric resonator, there is also an elastic wave (a transverse acoustic mode) propagating in the direction parallel to the upper electrode and the lower electrode. According to the transverse acoustic mode, waves are repeatedly reflected at or near the peripheral section of the vibration region and thus superimposed and amplified within the vibration region. When the elastic waves propagating in the transverse direction are superimposed and amplified in that manner, even very small amplitude of the elastic wave can interfere with the longitudinal acoustic mode and affect the vibration characteristic, leading to deterioration in characteristics of the resonator. Moreover, when the filter consists of the resonator is configured, insertion losses for the filter could increase, and phase characteristics could deteriorate.

A conventional, typical thin film piezoelectric resonator has the vibration region that is rectangular, especially square or circular, in shape. Therefore, the characteristics of the filter or the resonator can easily deteriorate due to the transverse acoustic mode. The deterioration of such characteristics makes it difficult to apply the thin film piezoelectric resonator like FBAR or SMR to the RF device.

Conventionally, there are proposals concerning methods for preventing the deterioration of characteristics by the above-mentioned, unnecessary transverse acoustic mode, for example, such as those disclosed in Patent Documents 1 to 3.

According to the method disclosed in Patent Document 1, a frame is formed at the edge section of the upper electrode to reduce the occurrence of noise by the transverse acoustic mode.

According to the method disclosed in Patent Document 2, since the shape of the vibration region whose piezoelectric layer is sandwiched between the upper electrode and the lower electrode is a polygon having no pair of sides extending in parallel, the occurrence of noise by the transverse acoustic mode is reduced.

According to the method disclosed in Patent Document 3, the shape of the vibration region is an ellipse whose ratio of the longitudinal axis to the transverse axis in length is greater than or equal to 1.9, and less than or equal to 5. Therefore, even when the spurious of an inharmonic mode appears due to principal vibration, the intensity of the spurious can be effectively reduced.

Patent Document 1: U.S. Pat. No. 6,788,170
Patent Document 2: U.S. Pat. No. 6,215,375

### Patent Document 3: JP-A-2003-133892

### DISCLOSURE OF THE INVENTION

### Problems to be Solved by the Invention

Therefore, according to the method disclosed in Patent Document 1, a process of forming the frame is necessary. Moreover, the line width of the frame must be on the order of μm. Therefore, considering such things as the accuracy of the position with respect to the upper electrode, extremely high precision is required for processing, making it difficult to produce and therefore leading to a rise in production costs.

According to the method disclosed in Patent Document 2, when many resonators are arranged to form the filter, it is difficult to arrange the resonators orderly. Therefore, the problem is that the filter cannot be made small. Moreover, Q-value declines at an anti-resonant frequency, leading to deterioration in characteristics.

According to the method disclosed in Patent Document 3, since the shape of the vibration region is an elongated shape which is very different from an circle that is ideal to achieve a high Q-value, the Q-value plunges, leading to deterioration in quality factors of the resonator's characteristics. Therefore, the characteristics of the filter including such a resonator deteriorate.

The present invention has been made in view of the above points. The object of the present invention is to provide at low cost the thin film piezoelectric resonator which can reduce the occurrence of unnecessary transverse acoustic mode and which has a high Q-value. Moreover, another object of the present invention is to make it easy to offer the small-size thin film piezoelectric filter having excellent characteristics.

### Means for Solving the Problems

According to the present invention, in order to achieve the above objects, there is provided a thin film piezoelectric resonator comprising:

a piezoelectric resonant stack containing a piezoelectric layer, and an upper electrode and a lower electrode which are formed so as to face each other across the piezoelectric layer; and

a substrate supporting the piezoelectric resonant stack,

wherein the piezoelectric resonant stack includes a vibration region where the upper electrode and the lower electrode face each other across the piezoelectric layer and primary thickness longitudinal vibration is possible, and a supporting region supported by the substrate,

the shape of the vibration region is an ellipse whose ratio a/b of the major axis a to the minor axis b is greater than or equal to 1.1, and less than or equal to 1.7,

the piezoelectric resonant stack further includes an upper dielectric layer formed on the upper electrode, and

the ratio c/d of the total thickness c of the upper electrode plus the upper dielectric layer in the vibration region to the thickness d of the piezoelectric layer in the vibration region is greater than or equal to 0.25, and less than or equal to 0.45.

According to one aspect of the present invention, the piezoelectric resonant stack further includes a lower dielectric layer formed below the lower electrode. According to one aspect of the present invention, an air gap or an acoustic impedance converter is formed on the substrate such that the air gap or the acoustic impedance converter corresponds to the vibration region and that the primary thickness longitudinal vibration of the vibration region is possible.

Moreover, according to the present invention, in order to achieve the above objects, there is provided a thin film piezoelectric filter that is a filter circuit formed by connecting a plurality of thin film piezoelectric resonators, each being the above thin film piezoelectric resonator.

### ADVANTAGEOUS EFFECTS OF THE INVENTION

According to the thin film piezoelectric resonator of the present invention, the shape of the vibration region is an ellipse whose ratio a/b of the major axis a to the minor axis b is greater than or equal to 1.1, and less than or equal to 1.7, and the ratio c/d of the total thickness c of the upper electrode plus the upper dielectric layer in the vibration region to the thickness d of the piezoelectric layer in the vibration region is greater than or equal to 0.25, and less than or equal to 0.45. Therefore, the thin film piezoelectric resonator that has reduced the occurrence of the transverse acoustic mode and has a high Q-value can be realized.

### BRIEF DESCRIPTION OF THE DRAWINGS

FIG. 1 is a diagram showing a thin film piezoelectric resonator according to an embodiment of the present invention, wherein (a) is a schematic plan view and (b) is a schematic cross-sectional view of (a) taken along line X-X;

FIG. 2 is a diagram showing a thin film piezoelectric resonator according to an embodiment of the present invention, wherein (a) is a schematic plan view and (b) is a schematic cross-sectional view of (a) taken along line X-X;

FIG. 3 is a diagram showing a thin film piezoelectric resonator according to an embodiment of the present invention, wherein (a) is a schematic plan view and (b) is a schematic cross-sectional view of (a) taken along line X-X;

FIG. 4 is a diagram showing a thin film piezoelectric resonator according to an embodiment of the present invention, wherein (a) is a schematic plan view and (b) is a schematic cross-sectional view of (a) taken along line X-X;

FIG. 5 is a schematic cross-sectional view of the thin film piezoelectric resonator according to an embodiment of the present invention;

FIG. 6 is a diagram showing a ladder filter circuit which is an embodiment of a thin film piezoelectric filter using a thin film piezoelectric resonator of the present invention;

FIG. 7 is a diagram showing (a) impedance and phase characteristics of a thin film piezoelectric resonator of the present invention obtained in Example 1, and (b) filtering characteristics of a filter using the thin film piezoelectric resonator;

FIG. 8 is a diagram showing (a) impedance and phase characteristics of a thin film piezoelectric resonator obtained in Comparative Example 1, and (b) filtering characteristics of a filter using the thin film piezoelectric resonator;

FIG. 9 is a diagram showing (a) impedance and phase characteristics of a thin film piezoelectric resonator obtained in Comparative Example 2, and (b) filtering characteristics of a filter using the thin film piezoelectric resonator;

FIG. 10 is a diagram showing impedance characteristics of a thin film piezoelectric resonator of the present invention obtained in Example 2;

FIG. 11 is a diagram showing the change in noise intensity in the case of the amplitude characteristic of a resonator when the ratio a/b of the major axis a to the minor axis b of the shape of an ellipse of the vibration region of the thin film piezoelectric resonator is changed;

FIG. 12 is a diagram showing the change in quality factor when the ratio a/b of the major axis a to the minor axis b of the shape of an ellipse of the vibration region of the thin film piezoelectric resonator is changed;

FIG. 13 is a diagram showing the change in electromechanical coupling factor when the ratio c/d of the total thickness c of the upper electrode plus upper dielectric layer of the thin film piezoelectric resonator to the thickness d of the piezoelectric layer is changed; and

FIG. 14 is a diagram showing the change in electromechanical coupling factor when the ratio c/d of the total thickness c of the upper electrode plus upper dielectric layer of the thin film piezoelectric resonator to the thickness d of the piezoelectric layer is changed.

### LIST OF REFERENCE SIGNS IN THE DRAWINGS

2: piezoelectric layer
4: air gap
6: substrate
8: lower electrode
10: upper electrode
12: piezoelectric resonant stack
14A, 14B: connection conductor
18: vibration region
19: supporting region
20: upper dielectric layer
21: lower dielectric layer
22: acoustic impedance converter
28: through hole for etching sacrifice layer
30: SiO₂ layer
100: thin film piezoelectric filter
101, 102: input/output port
111, 113, 115: series thin film piezoelectric resonator
112, 114 116: parallel thin film piezoelectric resonator

### BEST MODE FOR CARRYING OUT THE INVENTION

Hereinafter, embodiments of the present invention will be described with reference to the accompanying drawings.

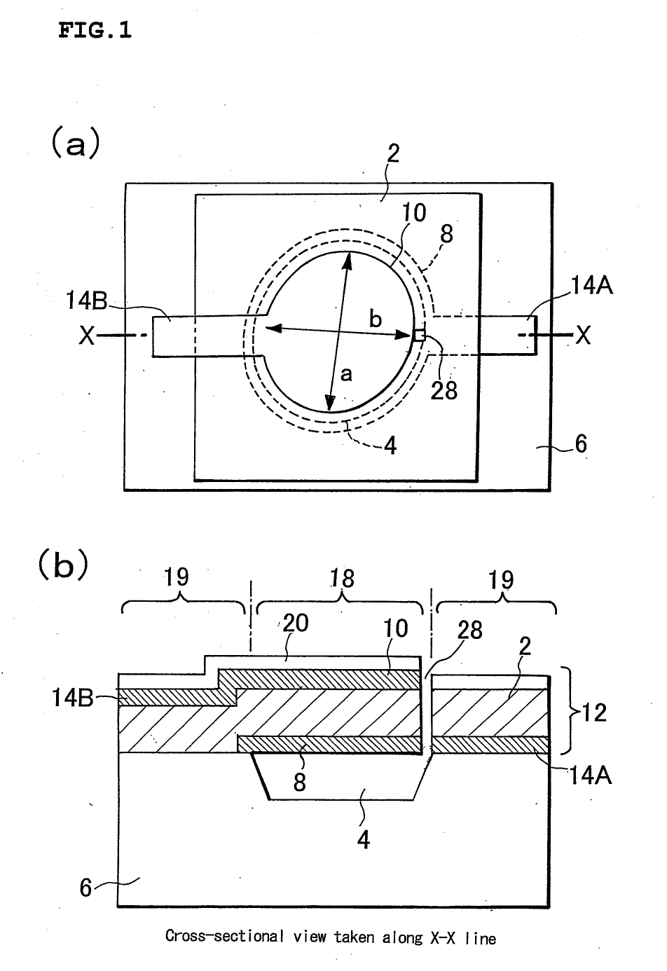

FIG. 1 shows a thin film piezoelectric resonator according to an embodiment of the present invention. FIG. 1(a) is a schematic plan view of the thin film piezoelectric resonator, while FIG. 1(b) is a schematic cross-sectional view of FIG. 1(a) taken along line X-X.

According to the present embodiment, the thin film piezoelectric resonator includes a piezoelectric resonant stack or piezoelectric resonator stack 12; an air gap 4 formed below the piezoelectric resonant stack; and a substrate 6 that supports the piezoelectric resonant stack so as to form the air gap.

The piezoelectric resonant stack 12 is a laminated body including: a piezoelectric layer (piezoelectric thin film) 2; a lower electrode 8 and an upper electrode 10 which are facing each other across the piezoelectric layer; and an upper dielectric layer 20 formed on the upper electrode. The upper dielectric layer 20 is not shown in FIG. 1(a). The piezoelectric resonant stack 12 is not limited to a region where the laminated structure is formed by the piezoelectric layer, the upper electrode, the lower electrode, and the upper dielectric layer. The piezoelectric resonant stack 12 includes a region where the upper electrode or the lower electrode are not formed. Within a plane parallel to a portion where the upper surface of the substrate 6 is in contact with the piezoelectric resonant stack 12, i.e. when viewed in the vertical direction, the piezoelectric resonant stack 12 includes a vibration region 18 where the lower electrode 8 and the upper electrode 10 overlap each other, and a supporting region 19 where the piezoelectric resonant stack 12 is in contact with the substrate 6.

An air gap 4 is formed below the vibration region 18. That is, the vibration region 18 is positioned so as to correspond to the air gap 4. Therefore, the primary thickness longitudinal vibration or primary thickness vertical vibration of the vibration region 18 is possible.

According to the present embodiment, when viewed in the vertical direction, the shape of the vibration region 18 where the piezoelectric layer 2 is sandwiched between the lower electrode 8 and the upper electrode 10 is an ellipse or oval. Here, conductive thin films (referred to as connection conductors) 14A and 14B formed to connect the lower electrode 8 and the upper electrode 10 to an external circuit are not regarded as parts of the lower electrode and the upper electrode, respectively. That is, a region where the connection conductors are formed is not regarded as the vibration region 18. The boundaries of the connection conductors 14A and 14B, and the lower electrode 8 and the upper electrode 10 constitute the contour line of the vibration region 18. Therefore, the contour of the vibration region 18 is determined by extending part of the contour line that is not in contact with the connection conductor of the upper electrode 10 or the lower electrode 8. Moreover, according to the present embodiment, a through hole 28 for forming the air gap 4 is formed outside the vibration region. Therefore, the damage caused by an etching solution used for forming the air gap to the lower electrode 8, the piezoelectric layer 2, the upper electrode 10 and the upper dielectric layer 20 can be minimized. Furthermore, according to the present embodiment, since the piezoelectric resonant stack 12 does not have a region whose thickness is different within the vibration region, such effects as reducing the occurrence of spike noise which occurs around resonant frequency can be obtained.

According to the present embodiment, the shape of the vibration region 18 is an ellipse whose ratio a/b of the major axis or long diameter a to the minor axis or short diameter b is greater than or equal to 1.1, and less than or equal to 1.7. Therefore, as compared with a circular one with a/b of 1, the occurrence of spurious noise related to the transverse acoustic mode ban be reduced. Furthermore, the quality factors do not deteriorate, or even if the quality factors deteriorate, the degree of deterioration is small.

Moreover, according to the present embodiment, the ratio c/d of the total thickness c of the upper electrode 10 plus the upper dielectric layer 20 in the vibration region 18 to the thickness d of the piezoelectric layer 2 in the vibration region 18 is greater than or equal to 0.25, and less than or equal to 0.45. If the ratio c/d of the total thickness c of the upper electrode 10 plus the upper dielectric layer 20 to the thickness d of the piezoelectric layer 2 is greater than or equal to 0.25, the intensity of the transverse acoustic mode (transverse resonance mode) primarily propagating along the surface of the piezoelectric layer 2 is dispersed and reduced satisfactorily. Meanwhile, if the ratio c/d is less than or equal to 0.45, a good electromechanical coupling factor is obtained.

In that manner, as a result of the combined effect of the ratio a/b set in the specific range and the ratio c/d set in the specific range, the thin film piezoelectric resonator whose level of noise and Q-value are sufficient for practical use can be provided.

The substrate 6, for example, includes a silicon substrate, a gallium arsenide substrate, a glass substrate, and the like. The air gap 4 can be formed by anisotropic wet etching, RIE (Reactive Ion Etching), or the like. The piezoelectric layer 2, for example, is made from piezoelectric materials, such as zinc oxide (ZnO) or aluminum nitride (AlN), which can be made into thin films. Moreover, the material of the upper electrode 10 and the lower electrode 8 may be such metal materials as aluminum (Al), tungsten (W), molybdenum (Mo), platinum (Pt), ruthenium (Ru), iridium (Ir) or gold (Au), which can be made into thin films and to which patterning can be applied. The upper electrode 10 and the lower electrode 8 may be a single layer film made from the above metal materials, or a laminated body made from those metal materials. The material of the upper dielectric layer 20 is preferably such materials as AlN, AlON, Si₃N₄, and SiAlON which have a relatively large elastic modulus. When the upper dielectric layer 20 is provided, it becomes easy to keep the above ratio c/d within an appropriate range. Furthermore, it becomes possible to protect the upper electrode 10 from oxidative degradation.

According to the present embodiment, the thin film piezoelectric resonator can be produced in a manner described below. A pit section is formed on the substrate 6 such as a silicon wafer by such techniques as wet etching; a sacrifice layer or sacrificial layer is then formed by such film formation techniques as a CVD method. After that, the surface of the substrate and the surface of the sacrifice layer within the pit section are planarized by such planarization techniques as CMP method, resulting in the substrate where the sacrifice layer is formed only within the pit section. The sacrifice layer is preferably made from such materials as PSG (Phospho-silicate glass) which can be easily etched. On the substrate obtained as a result of undergoing the above procedures, the lower electrode 8, the piezoelectric layer 2 and the upper electrode 10 are formed as films by such film formation methods as a sputtering method or an evaporation method; patterning is applied to each layer by such patterning techniques as wet etching, RIE, or a lift-off method. Moreover, on the piezoelectric layer 2 and the upper electrode 10, the upper dielectric layer 20 is formed so as to cover the piezoelectric layer 2 and the upper electrode 10. Furthermore, the through hole 28 extending from the upper dielectric layer 20 to the sacrifice layer is formed by the above-mentioned patterning technique; an etching solution is supplied through the through hole to remove the sacrifice layer through an etching process. Therefore, the air gap 4 is formed in the pit section.

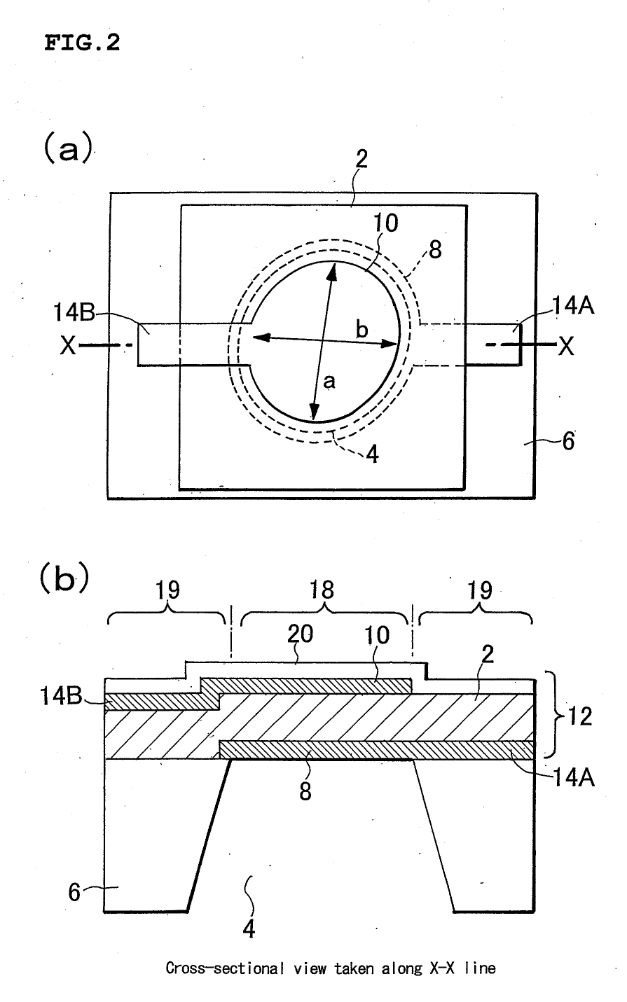

Moreover, besides the embodiment illustrated in FIG. 1, there are also other embodiments illustrated in FIGS. 2 to 5. Those embodiments are the same as the embodiment of FIG. 1 except the points described below.

FIG. 2 shows the thin film piezoelectric resonator according to an embodiment of the present invention. FIG. 2(a) is a schematic plan view of the thin film piezoelectric resonator, while FIG. 2(b) is a schematic cross-sectional view of FIG. 2(a) taken along line X-X. This embodiment is the same as the embodiment of FIG. 1 in terms of the air gap 4 formed on the substrate 6. However, this embodiment is different from the embodiment of FIG. 1 in that the through hole formed on the substrate 6 is used as the air gap 4.

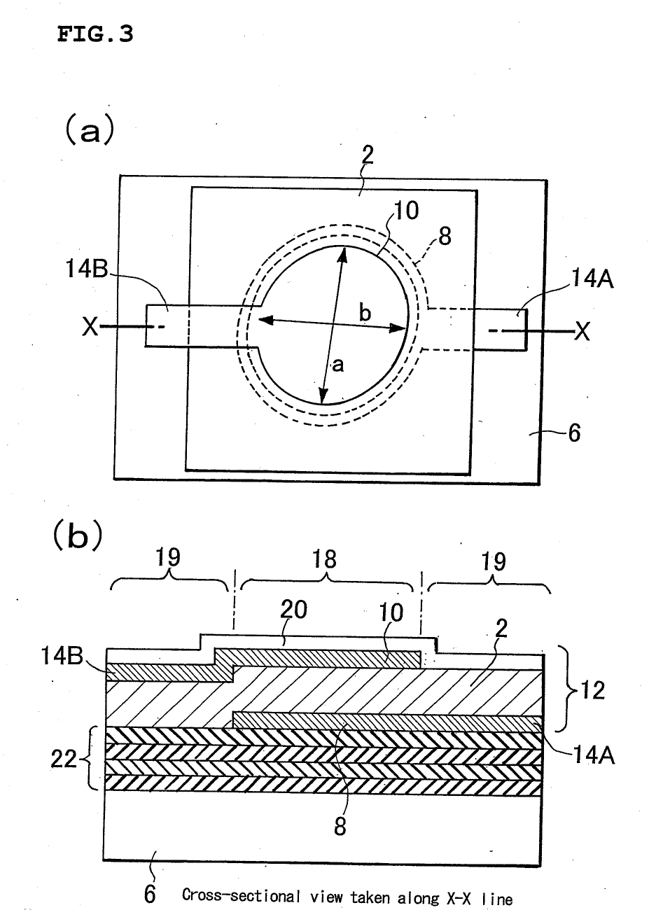

FIG. 3 shows the thin film piezoelectric resonator according to an embodiment of the present invention. FIG. 3(a) is a schematic plan view of the thin film piezoelectric resonator, while FIG. 3(b) is a schematic cross-sectional view of FIG. 3(a) taken along line X-X. According to this embodiment, an acoustic impedance converter 22 is provided instead of the air gap 4, whereby the primary thickness longitudinal vibration of the vibration region 18 is possible.

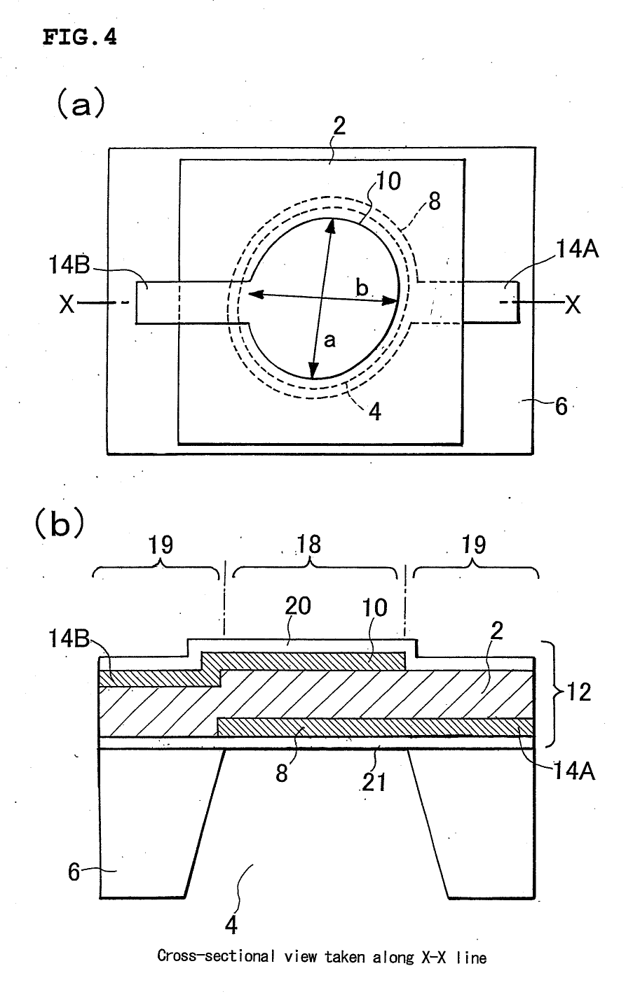

FIG. 4 shows the thin film piezoelectric resonator according to an embodiment of the present invention. FIG. 4(a) is a schematic plan view of the thin film piezoelectric resonator, while FIG. 4(b) is a schematic cross-sectional view of FIG. 4(a) taken along line X-X. According to this embodiment, the piezoelectric resonant stack 12 includes a lower dielectric layer 21 formed below the lower electrode 8. The material of the lower dielectric layer 21 may be the same as that of the upper dielectric layer 20. When the lower dielectric layer 21 is provided, it becomes possible to protect the lower electrode 8 from oxidative degradation.

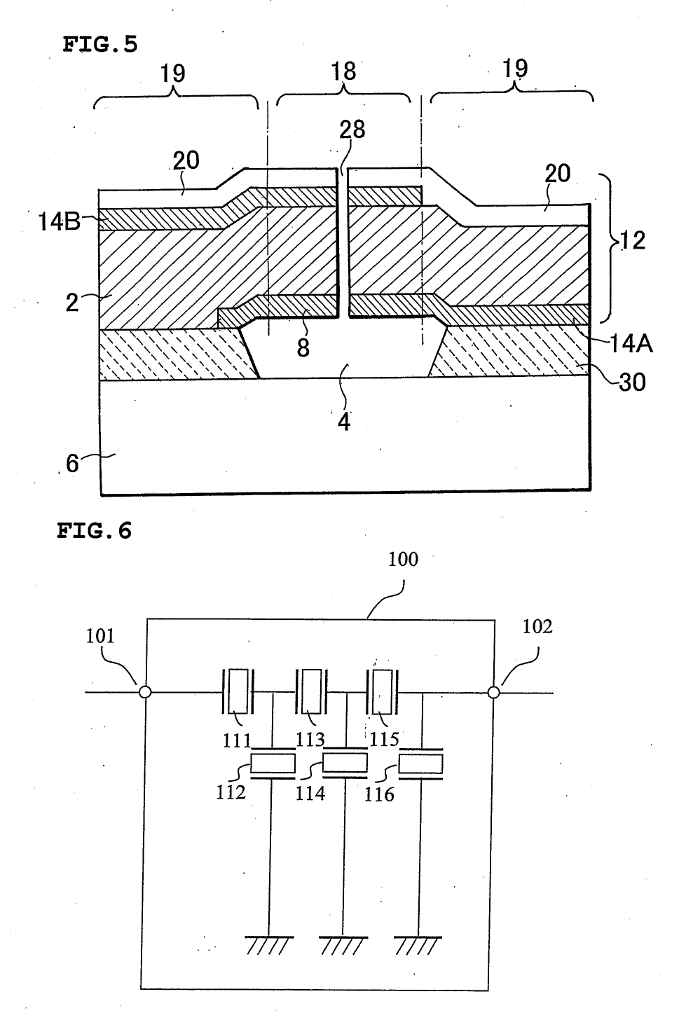

FIG. 5 is a schematic cross-sectional view of the thin film piezoelectric resonator according to an embodiment of the present invention. According to this embodiment, a silicon oxide (SiO₂) layer 30 is formed on the flat upper surface of the substrate 6; a through opening hole formed thereon is used as the air gap 4. According to this embodiment, the substrate 6 and the SiO₂ layer 30, as a whole, correspond to the substrate of the present invention.

The thin film piezoelectric resonator shown in FIG. 5 can be produced, for example, in a manner described below. The silicon oxide (SiO₂) layer 30 is formed on the substrate 6 such as a silicon wafer by such film formation techniques as a sputtering method and a CVD method, or thermal oxidation. After that, the sacrifice layer which can be easily dissolved in etching solution is formed by such film formation methods as a sputtering method or an evaporation method. Patterning is applied by such patterning techniques as wet etching, RIE, or a lift-off method. The sacrifice layer may be preferably such metal as germanium (Ge), aluminum (Al), titanium (Ti), and magnesium (Mg), or oxides thereof. After that, the lower electrode 8, the piezoelectric layer 2, the upper electrode 10, and the upper dielectric layer 20 are formed as films by such film formation methods as a sputtering method and an evaporation method; patterning is applied to each layer by such patterning techniques as wet etching, RIE, or a lift-off method. Moreover, the through hole 28 extending from the upper dielectric layer 20 to the sacrifice layer is formed by the above-mentioned patterning techniques; an etching solution is supplied through the through hole to remove the sacrifice layers through an etching process. Furthermore, an etching solution capable of etching the SiO₂ layer is selected to etch the SiO₂ layer. Therefore, the SiO₂ layer can be etched in the same pattern as the sacrifice layer. Therefore, the air gap is formed where the sacrifice layer and the SiO₂ layer were removed.

Even in the embodiments described above with reference to FIGS. 2 to 5, like the embodiment of FIG. 1, the thin film piezoelectric resonator having a high Q-value can be obtained without leading to deterioration in characteristics related to the transverse acoustic mode.

According to the present invention, as described above, the thin film piezoelectric resonator has the vibration region 18 that is to do with resonance. The shape of the vibration region 18 is an appropriate ellipse, while the total thickness c of the upper electrode 10 plus the upper dielectric layer 20 in the vibration region 18 is set appropriately. Therefore, without losing the high Q-value, the occurrence of noise related to the transverse acoustic mode can be reduced. Moreover, the thin film piezoelectric resonator whereby the loaded Q-value is large at anti-resonant frequency can be obtained.

FIG. 6 shows an example of a ladder filter circuit which is an embodiment of the thin film piezoelectric filter of the present invention. In this thin film piezoelectric filter 100, the thin film piezoelectric resonators 111, 113 and 115 of the present invention are used as series elements. The thin film piezoelectric resonators 111, 113 and 115 correspond to those described in the above embodiments. Moreover, thin film piezoelectric resonators 112, 114 and 116 of the present invention are used as shunt elements (parallel elements). The thin film piezoelectric resonators 112, 114 and 116 correspond to those described in the above embodiments. The reference numerals 101 and 102 denote input/output ports. The circuit configuration of the thin film piezoelectric filter of the present invention is not limited to that shown in FIG. 6. However, when the thin film piezoelectric filter is a ladder circuit, the configuration of the thin film piezoelectric filter becomes a lower-loss one.

### EXAMPLES

### Example 1

The thin film piezoelectric resonator described in the embodiment of FIG. 1 was produced. The shape of the vibration region is an ellipse with the major axis of 130 μm and the minor axis of 100 μm. According to the present example, the material and thickness of each constitutional layer was set in the following manner: the lower electrode was a layer made of Mo with thickness of 300 nm; the piezoelectric layer was a layer made of AlN with thickness of 1300 nm; the upper electrode was a layer made of Al with thickness of 300 nm; and the upper dielectric layer was a layer made of AlN with thickness of 150 nm. That is, the ratio a/b was 1.3, while the ratio c/d was 0.35.

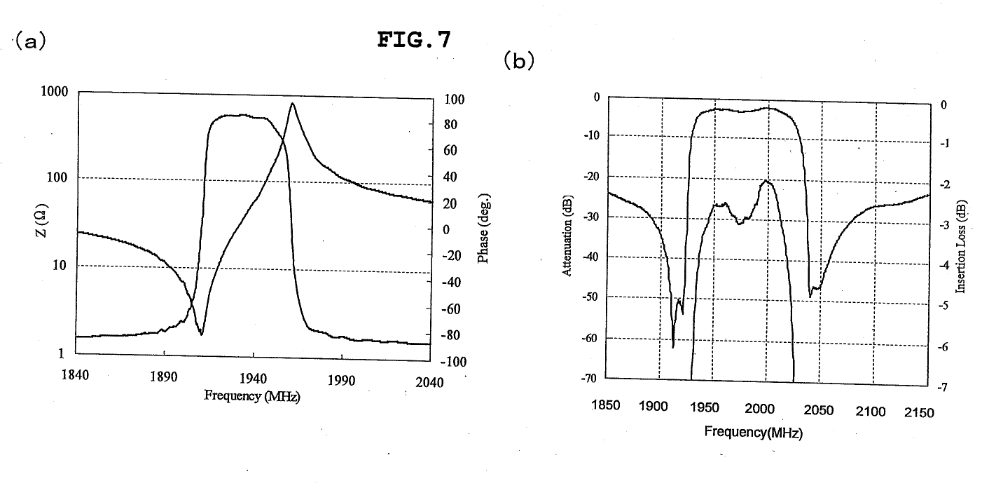

FIG. 7(a) shows the impedance and phase characteristics of the resonator produced in such a manner. It is obvious from FIG. 7(a) that the occurrence of noise related to the transverse acoustic mode was reduced, meaning that a good thin film piezoelectric resonator was obtained. Moreover, the loaded Q-value of the obtained thin film piezoelectric resonator at anti-resonant frequency is 600, which is a high value.

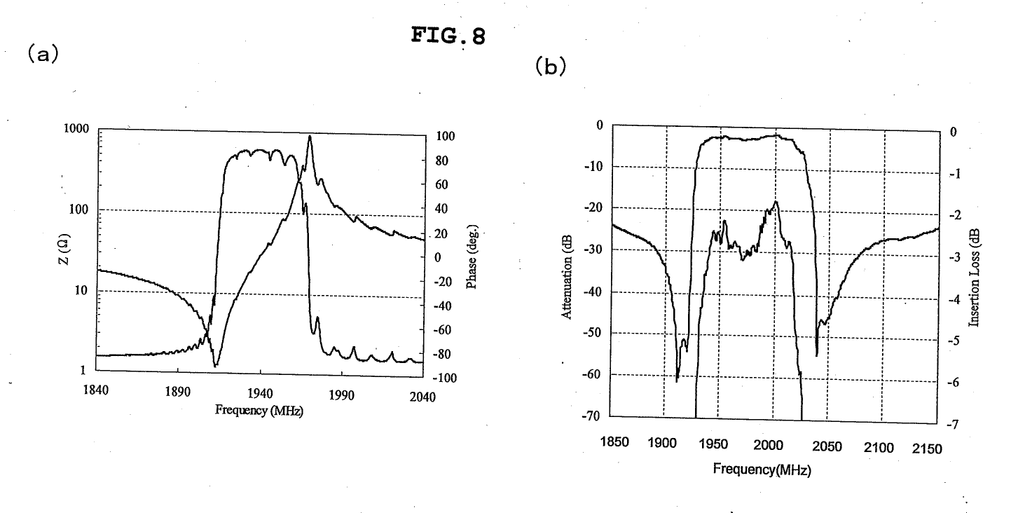

In that manner, six thin film piezoelectric resonators were produced. Using those thin film piezoelectric resonators, the thin film piezoelectric filter illustrated in FIG. 6 was produced. FIG. 7(b) shows the band-pass characteristics of the produced thin film piezoelectric filter. It is apparent that, as compared with the result of Comparative Example 1 described below with reference to FIG. 8(b), the occurrence of noise inside and outside a pass band was reduced, showing a good filtering characteristics.

### Comparative Example 1

The thin film piezoelectric resonator was produced in the same way as Example 1 except that the shape of the vibration region was an ellipse with the major axis of 116 μm and the minor axis of 112 μm. That is, the ratio a/b was 1.04, while the ratio c/d was 0.35.

FIG. 8(a) shows the impedance and phase characteristics of the obtained thin film piezoelectric resonator. It is obvious from FIG. 8(a) that the noise related to the transverse acoustic mode occurred, and that, as compared with the thin film piezoelectric resonator obtained in Example 1, the reduction in noise was insufficient.

In that manner, six thin film piezoelectric resonators were produced. Using those thin film piezoelectric resonators, the thin film piezoelectric filter illustrated in FIG. 6 was produced. FIG. 8(b) shows the band-pass characteristics of the produced thin film piezoelectric filter. It is apparent that a large amount of noise occurred inside and outside a pass band, and that the filtering characteristics deteriorated due to the transverse acoustic mode.

### Comparative Example 2

The thin film piezoelectric resonator was produced in the same way as Example 1 except that the thickness of the piezoelectric layer made of AlN was 1400 nm and that the upper dielectric layer was not formed. That is, the ratio a/b was 1.3, while the ratio c/d was 0.21.

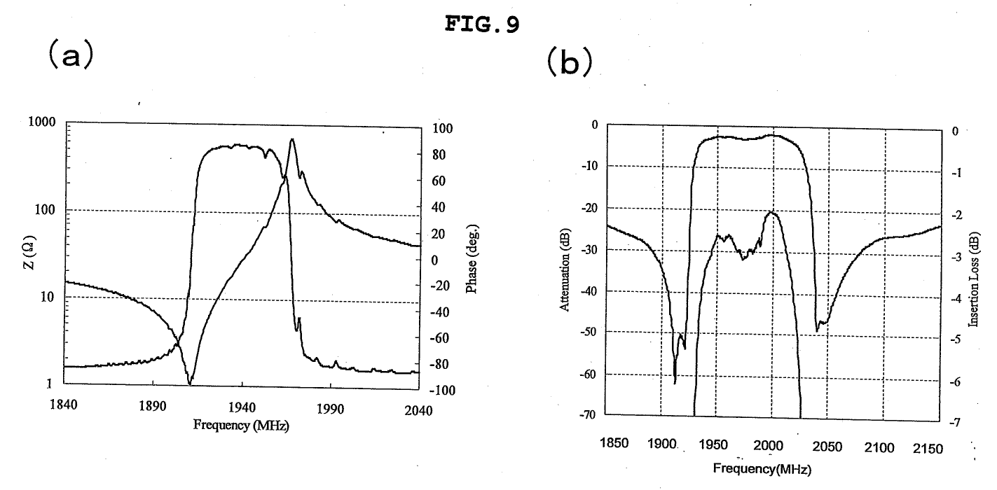

FIG. 9(a) shows the impedance and phase characteristics of the obtained thin film piezoelectric resonator. It is obvious from FIG. 9(a) that the noise associated with the transverse acoustic mode occurred, that the occurrence of the noise associated with the transverse acoustic mode was larger than that of the thin film piezoelectric resonator obtained in Example 1, and that the reduction in noise was insufficient.

In that manner, six thin film piezoelectric resonators were produced. Using those thin film piezoelectric resonators, the thin film piezoelectric filter illustrated in FIG. 6 was produced. FIG. 9(b) shows the band-pass characteristics of the produced thin film piezoelectric filter. It is apparent that a large amount of noise occurred inside a pass band, and that the filtering characteristics were not so good.

### Example 2

The thin film piezoelectric resonator was produced in the same way as Example 1 except that the shape of the vibration region was an ellipse with the major axis of 148 μm and the minor axis of 88 μm. That is, the ratio a/b was 1.68, while the ratio c/d was 0.35.

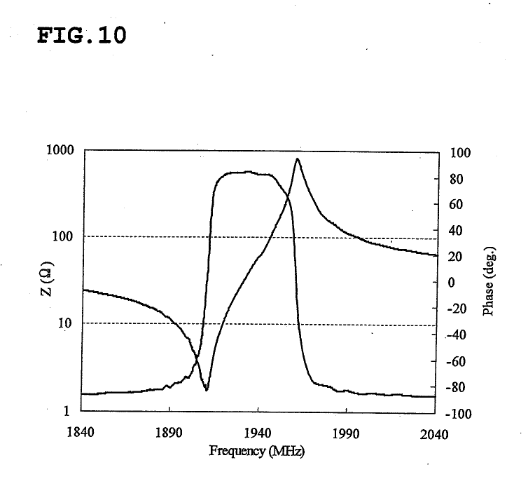

FIG. 10 shows the impedance and phase characteristics of the obtained thin film piezoelectric resonator. It is obvious from FIG. 10 that the occurrence of noise related to the transverse acoustic mode was reduced, meaning that a good thin film piezoelectric resonator was obtained. Moreover, the loaded Q-value of the obtained thin film piezoelectric resonator at anti-resonant frequency is 500, which is a high value.

### Example 3

A plurality of thin film piezoelectric resonators were produced in the same way as Example 1 while the ratio c/d was 0.35 and the ratio (ellipse ratio) a/b was changed with the area or size of the vibration region maintained at a constant level.

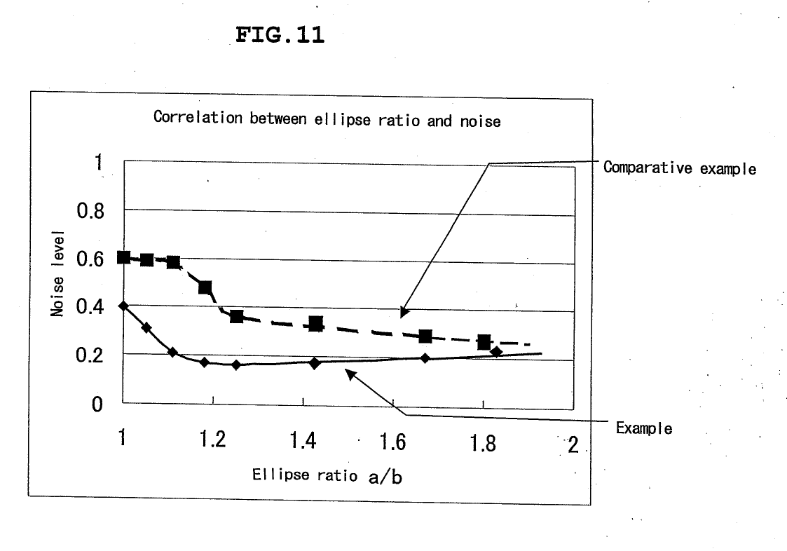

In FIG. 11, a solid line represents the change in noise level in the amplitude characteristics of the obtained thin film piezoelectric resonators. It is apparent from the diagram that the ratio a/b is related to the spurious intensity, and that setting the ratio a/b greater than or equal to 1.1 and less than or equal to 1.7 is an effective way to reduce the spurious intensity to less than or equal to 0.2 dB, which is required for practical use.

Moreover, a plurality of thin film piezoelectric resonators were produced in the same way as Comparative example 2 while the ratio c/d was 0.21 and the ratio (ellipse ratio) a/b was changed with the area or size of the vibration region maintained at a constant level.

In FIG. 11, a broken line represents the change in noise level in the amplitude characteristics of the obtained thin film piezoelectric resonator. It is apparent from the diagram that in order to reduce the spurious intensity to less than or equal to 0.2 dB, as suggested in Patent Document 3, the ratio a/b needs to be a large value exceeding the range of the present invention.

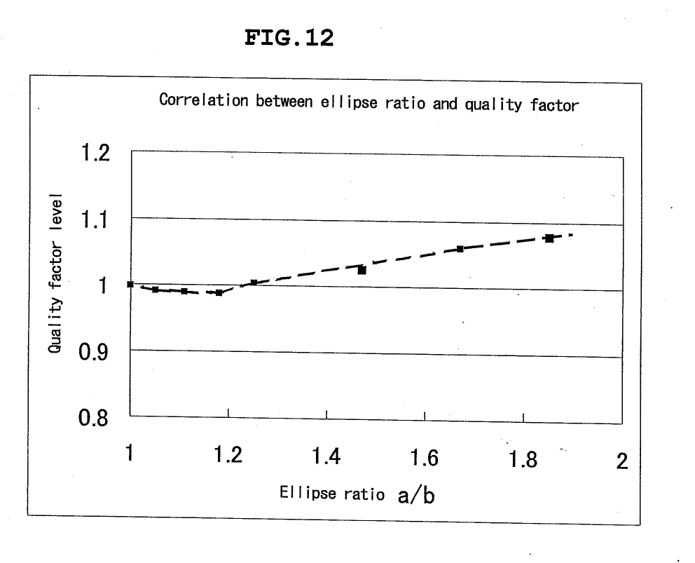

Moreover, FIG. 12 shows the change in quality factor level in the same case as Example 1 as described above while the ratio a/b was changed. It is apparent that when the ratio a/b exceeded the range of the present invention, the quality factors deteriorated further.

### Example 4

A plurality of thin film piezoelectric resonators were produced in the same way as Example 1 while the ratio a/b was 1.3 and the ratio (film-thickness ratio) c/d was changed. Here, when the ratio c/d was less than or equal to 0.21, the upper dielectric layer was not formed. When the ratio c/d was greater than 0.21, the ratio c/d was changed by forming the upper dielectric layer and changing the thickness of the upper dielectric layer while the thickness of the upper electrode was maintained at 300 nm.

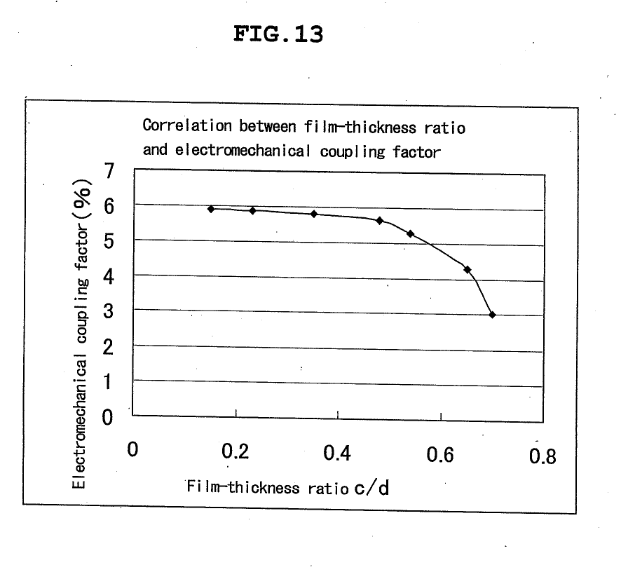

FIG. 13 shows the change in electromechanical coupling factor of the obtained thin film piezoelectric resonator. It is apparent from FIG. 13 that the value of electromechanical coupling factor decreased as the ratio c/d increased. The electromechanical coupling factor is an important factor in determining the width of a pass band when the filter includes the piezoelectric resonator. When the value of the electromechanical coupling factor is less than or equal to 5.7%, it is difficult to make the filter for practical use. Accordingly, it becomes clear that the ratio c/d needs to be less than or equal to 0.45.

### Example 5

A plurality of thin film piezoelectric resonators were produced in the same way as Example 4 except that the upper electrode was a laminated electrode made of Mo (Young's modulus=3.2×10¹¹ N/m²) and Al (Young's modulus=0.7×10¹¹ N/m²). The ratio a/b was 1.3, and the ratio (film-thickness ratio) c/d was changed. Here, as for the upper electrode, the thickness of the Mo layer was 150 nm; the thickness of the Al layer was 150 nm; the Mo layer was disposed on the side in contact with the piezoelectric layer; and the Al layer was disposed on the side in contact with the upper dielectric layer.

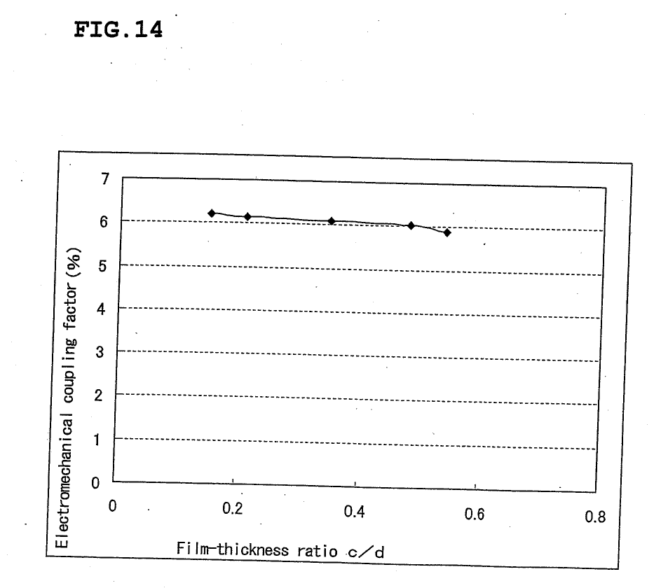

FIG. 14 shows the change in electromechanical coupling factor of the obtained thin film piezoelectric resonator. It is apparent that the electromechanical coupling factors shown in FIG. 14 are larger than those in FIG. 13. Therefore, it is obvious that when the laminated electrode has the Mo layer whose Young's modulus is relatively large on the piezoelectric-layer side, the larger electromechanical coupling factors can be obtained.

1. A thin film piezoelectric resonator comprising:
a piezoelectric resonant stack containing a piezoelectric layer, and an upper electrode and a lower electrode which are formed so as to face each other across the piezoelectric layer; and
a substrate supporting the piezoelectric resonant stack,
wherein the piezoelectric resonant stack includes a vibration region where the upper electrode and the lower electrode face each other across the piezoelectric layer and primary thickness longitudinal vibration is possible, and a supporting region supported by the substrate,
the shape of the vibration region is an ellipse whose ratio a/b of the major axis a to the minor axis b is greater than or equal to 1.1, and less than or equal to 1.7,
the piezoelectric resonant stack further includes an upper dielectric layer formed on the upper electrode, material of the upper dielectric layer being the same as that of the piezoelectric layer, and
the ratio c/d of the total thickness c of the upper electrode plus the upper dielectric layer in the vibration region to the thickness d of the piezoelectric layer in the vibration region is greater than or equal to 0.25, and less than or equal to 0.45.

2. The thin film piezoelectric resonator as claimed in claim 1, wherein the piezoelectric resonant stack further includes a lower dielectric layer formed below the lower electrode.

3. The thin film piezoelectric resonator as claimed in claim 1, wherein an air gap or an acoustic impedance converter is formed on the substrate such that the air gap or the acoustic impedance converter corresponds to the vibration region and that the primary thickness longitudinal vibration of the vibration region is possible.

4. A thin film piezoelectric filter that is a filter circuit formed by connecting a plurality of thin film piezoelectric resonators, each being the thin film piezoelectric resonator as claimed in claim 1.
